(19) United States
(12) Patent Application Publication
(10) Pub. No.: US 2007/0237198 A1
(43) Pub. Date: Oct. 11, 2007

(54) Vertical-stacked coupled quantum-dot vertical cavity surface emitting laser

(76) Inventors: Kuo-Jui Lin, Hsinchu (TW); Jyh-Shyang Wang, Hsinchu (TW); Ju-shiung Hsiao, Hsinchu (TW); Chiu-Yueh Liang, Hsinchu (TW)

Correspondence Address: HARNESS, DICKEY & PIERCE, P.L.C., P.O. BOX 8910, RESTON, VA, 20195, US

(21) Appl. No.: 11/228,380

(22) Filed: Sep. 19, 2005

(30) Foreign Application Priority Data
Dec. 29, 2004 (TW) 93141216

(51) Int. Cl. H01S 5/00

(52) U.S. Cl. 372/50.1

(57) ABSTRACT

A vertical-stacked coupled quantum-dot vertical cavity surface emitting laser includes a semiconductor substrate, a lower distributed Bragg reflector, a first wave guide layer, an emitting layer, a second wave guide layer and an upper distributed Bragg reflector. The emitting layer is formed by multiple Quantum-Dot Vertically Stacked layers, which are spaced less than 20 nm.

This application claims the benefit of Taiwan Patent Application No. 93141216, filed on Dec. 29, 2004, which is hereby incorporated by reference for all purposes as if fully set forth herein.

### BACKGROUND OF THE INVENTION

1. Field of Invention

The invention relates to a quantum-dot laser, and in particular to a vertical-stacked coupled quantum-dot laser having a spacer layer with reduced thickness.

2. Related Art

Theoretical research and physical implementation of quantum-dot lasers has been emphasized since the physical features of quantum dots were discovered in 1982. The quantum dot has been the prevalent material for optical communication because of the advantages of high temperature stability and low start current of quantum dot lasers.

Laser diodes are categorized into two types by their light emitting characteristics: edge-emitting lasers and surface-emitting lasers. Most conventional laser diodes adopt edge-emitting lasers. The emission method of vertical cavity surface emitting lasers (VCSEL) is the same as that of light emitting diodes. The surface-emitting lasers are the light source for premium lasers.

The light beam of the surface-emitting laser is emitted from the grain surface vertically, the main structure of which is the laser cavity formed of two multi-layer distributed Bragg reflectors (DBR). Furthermore, an active region, a p-type metal, and an N-type metal are also included. The light beam of the edge-emitting laser is emitted from the edges, while that of the surface-emitting laser is emitted from the front surface of the epitaxy.

For the general multi-layer stacked quantum dot laser, thicker spaces between layers are preferable to reduce the average stress of the stacked structure and reduce the dislocation. However, distribution and uniformity (size, shape and composition) of the self-assembled quantum dot laser are not easy to control such that photoluminescence and the light spectrum of the laser are distributed widely. This is worse when multi-layer quantum dot lasers are stacked vertically.

### SUMMARY OF THE INVENTION

In view of the foregoing, a vertical-stacked coupled quantum-dot vertical cavity surface emitting laser is provided according to the embodiments illustrated in the following.

According to an embodiment of the invention, the disclosed vertical-stacked coupled quantum-dot vertical cavity surface emitting laser comprises a semiconductor substrate; a lower distributed Bragg reflector layer formed on the semiconductor substrate; a first optical wave guide layer formed on the lower distributed Bragg reflector layer; an emitting layer, which is formed on the first optical wave guide layer having a plurality of vertical-stacked quantum dots; a second optical wave guide layer formed on the emitting layer; and a upper distributed Bragg reflector layer formed on the second optical wave guide layer.

According to the principle of the invention, the quantum dots have space layers less than 20 nm.

According to the principle of the invention, the quantum dots are formed by InAs, GaInAs, InSb, or GaInSb.

According to the principle of the invention, by implementing the vertical-stacked coupled structure on the edge emitting laser, the bandwidth of the laser beam is effectively reduced. Furthermore, the optical output power is increased and the start current is decreased.

In the following description, specific details are set forth in order to provide a thorough understanding of the invention. It will be apparent, however, to one skilled in the art that the invention can be practiced without these specific details. In other instances, structures and devices are shown in block diagram form in order to avoid obscuring the invention.

### BRIEF DESCRIPTION OF THE DRAWINGS

The above and other objects, features and other advantages of the invention will be more clearly understood from the following detailed description when taken in conjunction with the accompanying drawings, in which:

FIG. 1 illustrates the vertical-stacked coupled quantum-dot vertical cavity surface emitting laser of the invention;

FIG. 2 illustrates the current-voltage and current-optical output power diagram at room temperature when implementing the vertical-stacked coupled structure on the edge emitting laser;

FIG. 3 illustrates the intensity and wave length diagram of the vertical-stacked non-coupled edge emitting laser; and

FIG. 4 illustrates the intensity and wave length diagram of the vertical-stacked coupled edge emitting laser.

### DETAILED DESCRIPTION OF THE INVENTION

Reference is now made in greater detail to a preferred embodiment of the invention, an example of which is illustrated in the accompanying drawings. Wherever possible, the same reference numerals are used throughout the drawings and the description to refer to the same or like parts. Reference in the specification to “one embodiment” or “an embodiment” means that a particular feature, structure, or characteristic described in connection with the embodiment is included in at least one embodiment of the invention. The appearances of the phrase “in one embodiment” in various places in the specification are not necessarily all referring to the same embodiment.

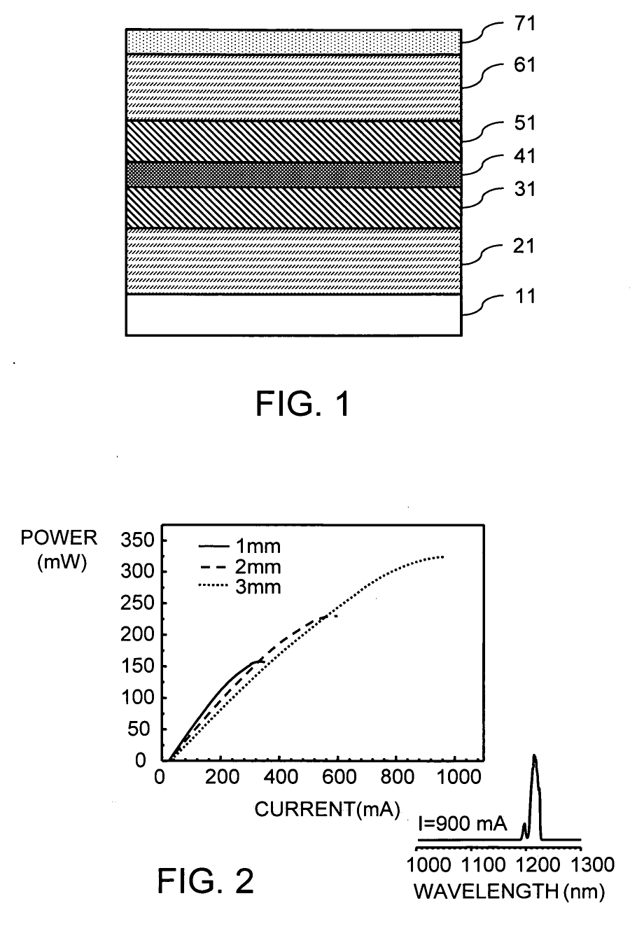

FIG. 1 illustrates the vertical-stacked coupled quantum-dot vertical cavity surface emitting laser of the invention. As illustrated in the figure, the laser includes a semiconductor substrate 11, a lower distributed Bragg reflector layer 21 formed on the semiconductor substrate 11, a first optical wave guide layer 31 formed on the lower distributed Bragg reflector layer 21, an emitting layer 41, which is formed on the first optical wave guide layer 31 by a plurality of vertical-stacked quantum dots; a second optical wave guide layer 51 formed on the emitting layer 41; and a upper distributed Bragg reflector layer 61 formed on the second optical wave guide layer 51. Furthermore, an electrode contact layer 71 is formed on the upper distributed Bragg reflector layer 61.

The semiconductor substrate 10 may be a Gallium Arsenide (GaAs) substrate. The lower distributed Bragg reflector layer 21 and the upper distributed Bragg reflector layer 21 are stacked alternately from multiple layers of AlGaAs and GaAs. The first optical wave guide layer 31 and the second optical wave guide layer 51 employ AlGaAs.

In the embodiment of a surface emitting laser, the emitting layer 40 is vertically stacked by InAs quantum dots in Molecular Beam Epitaxy (MBE). The space layers of the quantum dots in the emitting layer 40 are less than 20 nm such that the quantum dots in the emitting layer 40 may couple with one another.

The emitting layer 40 is an active region. The quantum dots in the emitting layer 40 are stacked in ten layers, in which each layer is separated from one another by 17 nm. Compared with the layers with spaces of 30 nm, the vertical-stacked coupled quantum laser of the invention may reduce the bandwidth of the laser spectrum effectively.

Refer to FIG. 2 illustrating the current-voltage and current-optical output power diagram of the vertical-stacked coupled edge emitting laser at room temperature. From the figure, the start current of the vertical-stacked coupled quantum dot edge emitting laser is 30 mA, the emitting efficiency is 0.45 W/A, and the optical output power is over 320 mW. Therefore, the performance of the disclosed vertical-stacked coupled quantum laser is better than that of the prior art.

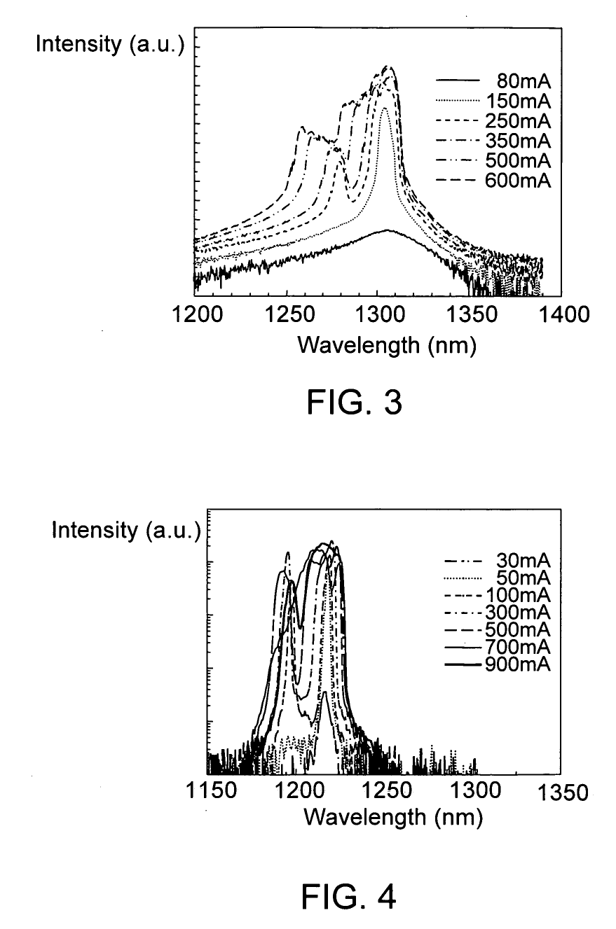

Refer to FIG. 3 illustrating the intensity and wave length diagram of the vertical-stacked non-coupled edge emitting laser, and FIG. 4 illustrating the intensity and wave length diagram of the vertical-stacked coupled edge emitting laser. In FIG. 3, the bandwidth of the laser spectrum of the vertical-stacked non-coupled edge emitting laser is wider, while in FIG. 4, the bandwidth of the laser spectrum of the vertical-stacked coupled edge emitting laser is narrower. Therefore, the performance of the surface emitting laser may be effectively improved through implementing the structure of the invention.

According to the principle of the invention, when space between layers of quantum dots is reduced to some extent, quantum dots in the upper layer automatically align on the lower layer due to the stress force of quantum dots in the lower layer. Therefore, ordered arrangement is formed. Meanwhile, the wave function of electrons in each layer creates a coupling effect because of the close space.

According to the principle of the invention, the dimensions for controlling quantum dots are increased by controlling the space layer thickness of the vertically-stacked quantum dots. Meanwhile, the coupled stack is some portion of the active region of the laser device. Carrier injection, carrier distribution, and light distribution may be modulated due to the change of the total thickness.

According to the principle of the invention, the coupling effect of the quantum dots in the emitting layer enables the excess carriers with lower recombination rate to migrate to the location with higher recombination rate through a quantum tunneling effect. Therefore, the emission intensity of the strongest resonant mode is effectively increased and the energy distributed in another spectrum is effectively lowered.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A vertical-stacked coupled quantum-dot laser, comprising:
an semiconductor substrate;
a lower distributed Bragg reflector layer formed on the semiconductor substrate;
a first optical wave guide layer formed on the lower distributed Bragg reflector layer;
an emitting layer, which is formed on the first optical wave guide layer, formed by a plurality of vertical-stacked quantum dots with space layers less than 20 nm;
a second optical wave guide layer formed on the emitting layer; and
a upper distributed Bragg reflector layer formed on the second optical wave guide layer.

2. The laser of claim 1, wherein the quantum dots are formed by InAs, GaInAs, InSb, or GaInSb.

3. The laser of claim 1, further comprises a electrode contacting layer formed on the upper distributed Bragg reflector layer.

4. The laser of claim 1, wherein the plurality of quantum dots comprises at least two to twenty layers.
